(19) United States
(12) Patent Application Publication
(10) Pub. No.: US 2006/0023516 A1
(43) Pub. Date: Feb. 2, 2006

(54) A Computerized Centralized Data Repository and process designated as primary source by multiple Primary Source Entities and accessible via electronic communications by multiple Requesting Entities to obtain Primary Source Data about Verification Subjects.

(75) Inventor: Andy Lock, San Diego, CA (US)

Correspondence Address: Andy Lock, 4411 Morena Blvd #100, San Diego, CA, 92117, US

(73) Assignee: WINSTAFF INC, San Diego, CA (US)

(21) Appl. No.: 11/161,351

(22) Filed: Jul. 29, 2005

Related U.S. Application Data
(60) Provisional application No. 60/522,011, filed on Aug. 2, 2004.

(51) Int. Cl. G11C 7/10

(52) U.S. Cl. 365/189.05

(57) ABSTRACT

A computerized centralized Primary Source Data Repository for storage and retrieval of Primary Source credentialing data. This invention includes a specific set of legal and administrative documentation and processes to ensure that data is accepted as Primary Source by accreditation agencies' regulations and state and federal laws. The invention is designed to contain multiple Primary Source entities' data in a single centralized database so that requesting entities' verification task is simplified by referring to a single source for multiple Primary Source Entities' Primary Source Data. In addition to processes, this data is centralized around a Verification Subject to improve speed and efficiency of searching for information. This data repository is available through one or more electronic mediums

### BACKGROUND OF INVENTION

Definitions:

Definition List 1

| Term | Definition |
|---|---|
| Primary Source Entity | an entity that is the creator, originator or |
| | official source of information specific to a |
| | Verification Subject. |
| Requesting Entity | a person or organization that requests information |
| | of a Verification Subject for the purpose of |
| | verifying this information. |
| Verification Subject | a person, place, or entity that is the subject of |
| | the verification such as health care practitioners |
| | and facilities, accountants, fitness trainers, etc. |
| Primary Source Data | Information about the Verification Subject that |
| | originates directly from a Primary Source Entity. |

1. Field of the Invention

This invention relates to the field of verification of a Verification Subject's credentials and Primary Source verification of credentials. This is also known in the industry as Credentialing.

2. Background of Related Art

Primary Source verification of professional credentials (such as that in the medical industry, professional industry, or any other regulated or self-regulated industry), is needed to ensure a Verification Subject is qualified to perform critical high-level services that can result in potentially catastrophic results if not performed properly by a qualified professional. In the example of a surgeon (Verification Subject), a hospital needs to verify that he or she is qualified to perform surgical procedures in their hospital. The hospital must verify the surgeon's credentials to decide if he or she is qualified to perform surgery. If this verification is not properly performed and the surgeon injures a patient during surgery in the hospital, that hospital would be potentially liable for damages due to negligence in verifying the surgeon's qualifications and allowing the surgery to take place in their facility. During the verification process, it is critical to ensure that the information to verify is received from a Primary Source Entity and not altered or reinterpreted by a third party. For example, to “Primary Source” verify a physician's completion of medical education, you must contact the medical school (Primary Source Entity) directly and not use a public hospital directory because of possible errors or reinterpretation in the hospital directory. However, it is also industry-accepted that non-Primary Sources of information, can act as a “display agent” for primary source of information on behalf of the original Primary Source Entity, as long as the “display agent” has been officially designated by the Primary Source as qualified to display/release such information.

There are multiple methods to request Primary Source information, such as phone calls, transmitting faxes, traditional mailing of request letters, personal meetings, review of printed rosters, and so forth. Most all of these suffer from one of two flaws: 1) inefficiency and 2) reliability. The traditional methods of communicating requests for information involve submitting a request and waiting for a human to receive this request and respond. This process is affected by human constraints such as existing workload, office hours, vacation, sickness, and so forth that can delay a response. In addition to human factors, other factors cause inefficiency such as logistical constraints like delay in traditional mail, or the delay in getting a fax or letter to the appropriate person within an organization. High costs also contribute to inefficiency due to wages, taxes, material costs, and postage costs.

Other methods, which marginally increase efficiency, such as Verification Subject rosters published by Primary Source Entities, introduce dangerous reliability issues. Due to the nature of how rosters have been traditionally published (print), the information is difficult to update. This information is only released every few months even though the information changes daily/weekly, thus providing outdated information for critical decisions regarding the quality of a Verification Subject.

Both of these methods also suffer from the fact that Primary Source Entity releases Primary Source Data differently. Therefore, to verify 10 pieces of information may require 10 different processes, thus adding to the complexity, inefficiency, and cost of the verification process. What is needed is a process and product that is a computerized centralized repository of information from multiple entities used for verification of data. The information in this repository must be qualified as Primary Source as required by accreditation agencies and legal statutes and easy to access via existing low-cost telecommunications technology such as the Internet.

### SUMMARY OF INVENTION

The invention is comprised of a computerized centralized data repository, which is accessible via electronic communications. This invention includes a specific set of legal and administrative documentation and processes to ensure that data is accepted as Primary Source by accreditation agencies' regulations and state and federal laws. The invention is designed to contain multiple Primary Source Entities' Credentialing Data in a single centralized database so that Requesting Entities' verification task is simplified by referring to a single source for multiple entities' information.

In one embodiment, invention's data can be organized around one or more Primary Source Data elements to improve speed and efficiency of searching for information.

In one embodiment, the invention is accessible via electronic networks such as the Internet or any other data network: wired or wireless.

In one embodiment, the invention is accessible via private company Intranets or private local area networks.

In one embodiment, the invention is accessible via telecommunication.

In one embodiment, the computerized centralized Primary Source Data Repository is utilized by other professional industries such as but not limited to finance, accounting, education, software development, and fitness training.

### DESCRIPTION OF DRAWINGS

The foregoing features and other aspects of the invention are explained in the following description taken in conjunction with the accompanying figures wherein:

FIG. 1 illustrates the business process of where Primary Source Data originates, how it is stored electronically in a Centralized Data Repository, and how each Primary Source Agreement between each Primary Source Entity and the Centralized Data Repository legally designates the Centralized Data Repository as containing Primary Source Data related to Verification Subjects for that Primary Source Entity. Referring first to FIG. 1, it shows that Primary Source Data originates from one or more Primary Source Entities 101. Each Primary Source Entity 101 signs a Primary Source Agreement 103 which designates the Centralized Data Repository 102 as the authorized “display agent” of their Primary Source Data. This document is a legal document. The Primary Source Data is then available electronically to Requesting Entities 104. The Primary Source Entities 101 electronically sends Primary Source Data to the Centralized Data Repository 102. The Centralized Data Repository 102 holds multiple Primary Source Entities' 101 Primary Source Data, which simplifies and expedites Requesting Entities' 104 searches for the desired Primary Source Data.

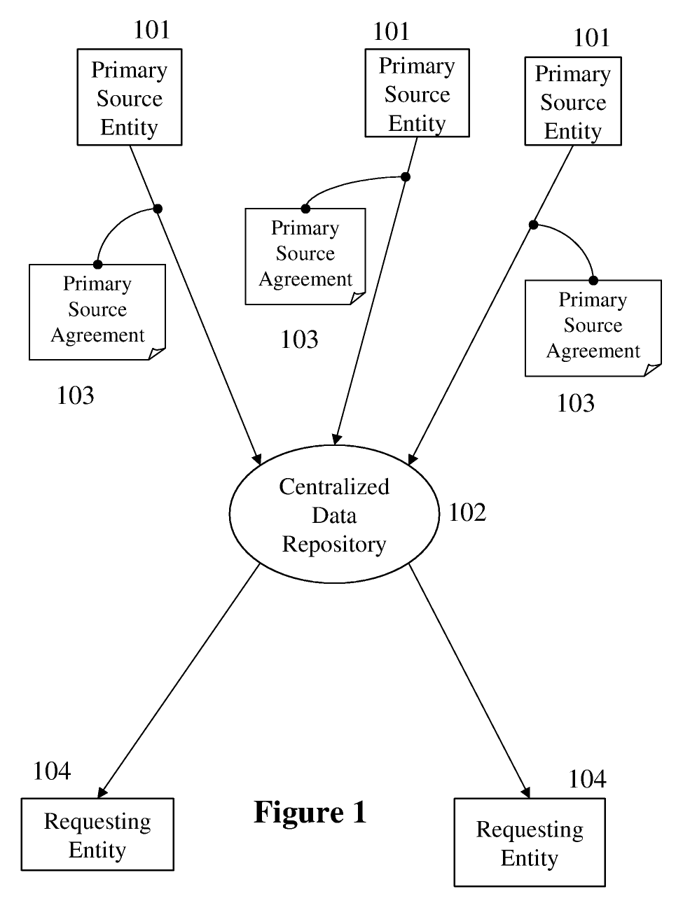

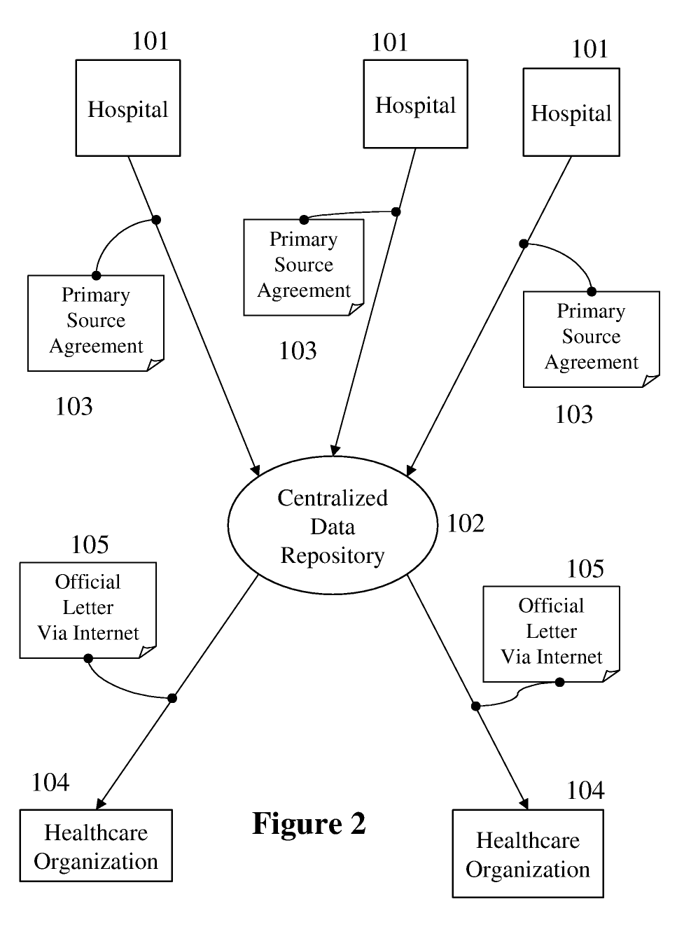

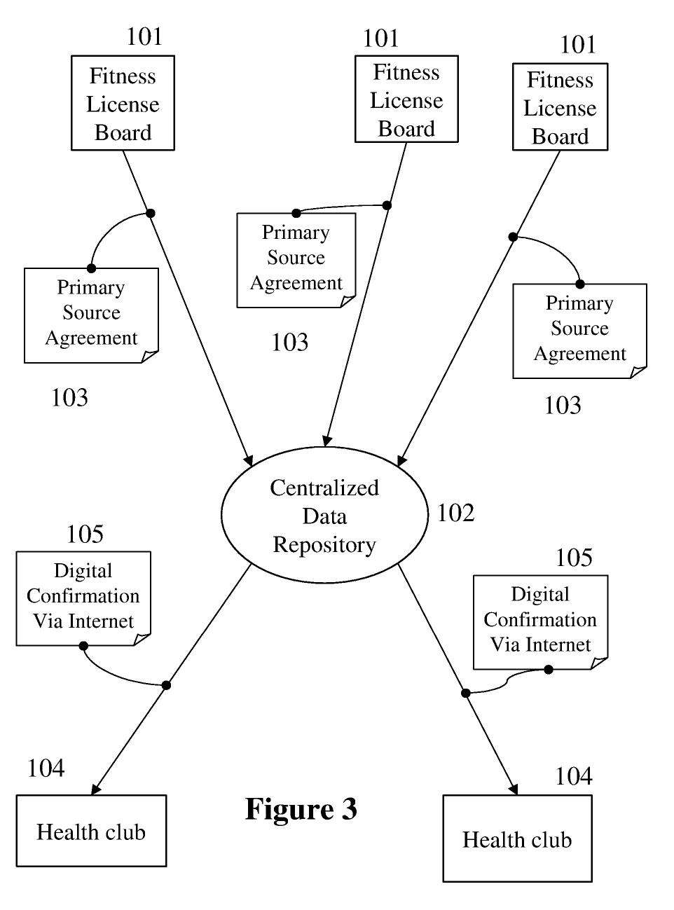

An embodiment of a Primary Source Entity 101 is shown in FIG. 2 as a Hospital 101. This figure shows how data is retrieved in an Official Letter format 105 using the Internet as the network medium. The Requesting Entities are Healthcare Organizations 104. The Primary Source Data stored in the Centralized Data Repository 102 would be related to a Verification Subject such as a Physician, Nurse, Allied Health Professional, etc.

An embodiment of a Primary Source Entity is shown in FIG. 3 as a Fitness License Board 101. This figure shows how data is retrieved in a digital confirmation format 105 using the Internet as the network medium. The Requesting Entities are Health Clubs 104. The Primary Source Data stored in the Centralized Data Repository 102 would be related to a Verification Subject such as a Fitness Trainer, Physical Therapist, etc.

It is understood that the drawings are for illustration only and are not limiting.

What is claimed is:

1. A system of a centralized data repository for storage and retrieval of data comprising of: (a) One or more Primary Source entities that submit their Primary Source Data to the centralized data repository, (b) A set of legal and administrative documentation and processes to ensure that the Primary Source Data submitted by the Primary Source Entity located on or transmitted through the centralized data repository is qualified as Primary Source by accreditation agencies' regulations and state and federal laws, and (c) Multiple Requesting Entities retrieve Primary Source Data from the data repository.

2. A system according to claim 1 wherein the Primary Source Data is organized around one or more Primary Source Data elements, Verification Subjects, and/or Requesting Agencies to improve speed and efficiency of searching for information.

3. A system according to claim 1 wherein the Primary Source Data is accessible via electronic networks such as the Internet, private company Intranets, private local area networks, or any other data or telecommunications network: wired or wireless.
